(19) United States
(12) Patent Application Publication
(10) Pub. No.: US 2026/0147486 A1
(43) Pub. Date: May 28, 2026

(54) SYSTEM FIRMWARE SOLUTION TO IMPROVE QUALITY OF SERVICE (QOS) OF OPEN BLOCKS IN NAND FLASH DEVICES BY REDUCING VPASSR

(71) Applicant: Microchip Technology Incorporated, Chandler, AZ (US)

(72) Inventors: Salvatrice Scommegna, CORNATE D'ADDA (IT); Pitamber Shukla, San Jose, CA (US); Antonio Aldarese, VIMERCATE (IT); Michele Cirella, Castelmassa (IT)

(73) Assignee: Microchip Technology Incorporated, Chandler, AZ (US)

(21) Appl. No.: 19/176,366

(22) Filed: Apr. 11, 2025

Related U.S. Application Data
(60) Provisional application No. 63/723,819, filed on Nov. 22, 2024.

(51) Int. Cl. G06F 3/06; G11C 16/04; G11C 16/26

(52) U.S. Cl. CPC G06F 3/0619; G06F 3/0659; G06F 3/0679; G11C 16/0483; G11C 16/26

(57) ABSTRACT

A computer-implemented method for reducing errors in a NAND flash device, the method comprising: determining an open block state of a block of NAND flash included in the NAND flash device, the block of NAND flash including a plurality of wordlines (WLs) including a selected WL and an unselected WL; responsive to determining that the block of NAND flash is in an open state, determining an adjusted pass-through voltage (Vpassr); and performing a read operation on the selected WL by applying the adjusted Vpassr to the unselected WL.

### CROSS-REFERENCE TO RELATED APPLICATIONS

The current patent application claims the benefit under 35 U.S.C. § 119(e) of the priority date of U.S. Provisional Application Ser. No. 63/723,819, titled “SYSTEM FIRMWARE SOLUTION TO IMPROVE QUALITY OF SERVICE (QOS) OF OPEN BLOCKS IN NAND FLASH DEVICES BY REDUCING VPASSR,” filed Nov. 22, 2024. The Provisional Application is hereby incorporated by reference, in its entirety, into the current patent application.

### TECHNICAL FIELD

Various examples of the present disclosure relate to systems and methods for reducing read errors in an open (e.g., at least partially unprogrammed) block of a NOT-AND (NAND) flash device, such as a solid-state drive (SSD), by performing a read operation on a last-written wordline (LWL) of the open block by applying an adjusted Vpassr to one or more of the unselected wordlines (UWLs).

### BACKGROUND

NAND flash devices, such as SSDs, may be susceptible to an increase in read errors experienced over time, e.g., as the physical blocks of NAND flash media included in the device wear through ordinary use. As the number of read errors experienced by a NAND flash device increases, the reliability of the operations being performed on/by the device, and the lifespan of the device, decreases. The present disclosure seeks to decrease the number of read errors in a NAND flash device.

This background discussion is intended to provide information related to the present invention which is not necessarily prior art.

### SUMMARY OF THE INVENTION

According to various examples of the present disclosure, a computer implemented method for improving quality of service (or “QoS”) of and/or reducing (read) errors in a NAND flash device may include: determining an open block state of a block of NAND flash included in the NAND flash device, the block of NAND flash including a plurality of wordlines (WLs) including a selected WL and an unselected WL; responsive to determining that the block of NAND flash is in an open state, determining an adjusted pass-through voltage (Vpassr); and performing a read operation on the selected WL by applying the adjusted Vpassr to the unselected WL.

According to various examples of the present disclosure, a controller of a NAND flash device is provided that includes non-transitory media having instructions stored thereon. The instructions, when executed by at least one processor, may cause the processor(s) to: determine an open block state of a block of NAND flash included in a NAND flash device, the block of NAND flash including a plurality of WLs including a selected WL and an unselected WL; responsive to determining that the block of NAND flash is in an open block state, determine an adjusted Vpassr; and perform a read operation on the selected WL by applying the adjusted Vpassr to the unselected WL.

In various examples of the present technology, one of ordinary skill will appreciate, in keeping with conventional patent drafting principles, that reference to a single example UWL of a block does not exclude the possibility of multiple UWLs in the block. NAND block(s) commonly include a plurality of UWLs. Similarly, one of ordinary skill will appreciate, in keeping with conventional patent drafting principles, that reference to application of an adjusted Vpassr to a single example UWL does not exclude the possibility of applying the adjusted Vpassr, another adjusted Vpassr, and/or another Vpassr to other of the plurality of UWLs of the block(s). In various examples, the adjusted Vpassr will be applied to multiple of the UWLs, another adjusted Vpassr will be applied to multiple other of the UWLs, and/or another Vpassr will be applied to still other of the UWLs, in a variety of combinations, including those combinations discussed in more detail elsewhere herein.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1 illustrates an example system for reducing read errors in a NAND flash device;

FIG. 2 illustrates an example computing system of the system of FIG. 1 connected to a communication network;

FIG. 3 illustrates an example data storage system of the system of FIG. 1;

FIG. 4 illustrates an example non-volatile memory (NVM) media of the system of FIG. 1;

FIG. 5 illustrates an example multi-plane block of an NVM of the system of FIG. 1;

FIG. 6 illustrates an example multi-plane wordline (WL) of the multi-plane block of FIG. 5;

FIG. 7 illustrates an example block of the example system of FIG. 1;

FIG. 8 illustrates an example block of the example system of FIG. 1; and

FIG. 9 illustrates an example method flow for reducing read errors in a NAND flash device.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, operations, features, functions, or the like.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

In addition, use of “a” or “an” are employed to describe elements and components of the embodiments herein. This is done merely for convenience and to give a general sense of the description. Uses of “a” or “an” in this description, and the claims that follow, should be read to mean at least one unless plainly stated otherwise.

In various examples of the present disclosure, a data storage system may include a memory device and a controller. The memory device may store data. The data storage system may be connected to a host system. In various examples, the data storage system may be connected to the host system by wired or wireless means. In various examples, the data storage system may be connected to more than one host system, such as in a multi-tenant environment, without limitation. The controller may be operable to manage storage and retrieval of data to and from the memory device. The host system may send data to the data storage system for storage in the memory device. The controller may process the data and issue commands to the memory device for storing the data in the memory device. The host system may send a read request to the data storage system. The read request may indicate data to be retrieved from the memory device and sent back to the host system. The controller may process the read request, retrieve the data from the memory device, process the retrieved data, and send the retrieved data to the host system.

In various examples, the memory device may be a solid-state drive (SSD) including a plurality of non-volatile memory (NVM) media (e.g., NAND-based memory media) for data storage. In various examples, the NVM media may include chip enable (CE) ports which may also be referred to as “targets.” Examples may be used in single-level cell (SLC) systems, multi-level cell (MLC) systems, triple-level cell (TLC) systems, quad-level cell (QLC) systems, and penta-level cell (PLC) systems, without limitation. Applications may include consumer hard drives, high performance computing (HPC), data transfer for AI, and data center solutions (DCS), without limitation.

The NVM media may respectively include a local controller and a plurality of die. In various examples, the NVM media may respectively include two (2), four (4), eight (8), sixteen (16), twenty four (24), thirty two (32), or more die, without limitation. Each die may correspond to a logical unit (LUN). Each LUN may include a plurality of planes. Each LUN may include, for example, four (4), six (6), eight (8), or more planes, without limitation. Each plane may include a cache register, a page register, and a plurality of physical memory blocks.

When data is written to or retrieved from the NVM media, the data may be temporarily stored in one of the cache register and the page register. Each physical memory block may include a set of pages. The cache register and the page register may respectively have an equivalent data capacity of one page. Accordingly, data to be written to a first page may be temporarily stored in the cache register while data to be written to another page may be temporarily stored in the page register. Data to be read from a first page may be retrieved and temporarily stored in the cache register while data to be read from another page may be stored in the page register. Accordingly, the cache register and page register enable double buffering of data to reduce data programming and read times. Each page may include a plurality of cells. Each cell may include a transistor having a gate, a source, and a drain. Data bits may be written to the plurality of cells on a page-by-page basis. Data may be erased from the plurality of cells on a physical memory block basis.

The NVM media may additionally include a plurality of wordlines (WLs) and a plurality of bitlines (BLs). Generally, WLs connect the gates of each cell included in a row of cells. BLs may be connected to the drain of each cell. A row of cells having their gates connected by a WL may be referred to as a page. BLs can either connect the drain of a cell to the source of a cell in an adjacent row or to “ground” (e.g., true ground, 0V, Vcc, etc.). As used herein, an “adjacent” row or wordline is one that is physically nearest within a given logical grouping, it being understood that where cells are physically and/or logically arranged in a regular array or grid, such as in rows and columns, each row or most rows may respectively have two (2) adjacent rows (that is, the physically nearest row on either side in the array or grid). When a voltage is applied to a specific WL, cells included in that WL are accessible for writing/programming or reading. Data is stored in and/or transferred to/from cells during read/write operations via BLs. In other words, WLs effectively address rows of cells where data is being programmed to or read from, while BLs are highways on which data travel to reach the desired cell(s).

In various examples, the cells may include single-level cells (SLCs), multi-level cells (MLCs), triple-level cells (TLCs), quadruple-level cells (QLCs), and/or penta-level cells (PLCs), without limitation. Accordingly, the WLs may be SLC WLs, MLC WLs, QLC WLs and/or PLC WLs, without limitation. In an example, a TLC multi-plane WL may span four (4) planes. The four (4) planes may respectively include a lower page, a middle page, and an upper page of the WL. The lower page, middle page, and upper page may correspond to a page including a string of TLCs. The TLC multi-plane WL may be activated to write data to each of the upper, middle, and lower pages of each of the four (4) planes. Accordingly, an SLC WL may be associated with one (1) page from each plane, an MLC WL may include two pages (2) from each plane, a TLC WL may include three (3) pages from each plane, a QLC WL may include four (4) pages from each plane, and a PLC WL may include five (5) pages from each plane.

In various examples, the physical blocks of each LUN may be organized into multi-plane blocks. A multi-plane block may include a set of blocks of a particular LUN. For example, a first block of a first plane of a first LUN, a first block of a second plane of the first LUN, a first block of a third plane of the first LUN, and a first block of a fourth plane of the first LUN may be organized into a multi-plane block. Accordingly, each LUN may include a number of multi-plane blocks equal to a number of physical blocks in one plane of a particular LUN, and each multi-plane block may include one (1) physical block from each plane of the particular LUN.

Each physical block of each multi-plane block may include a set of pages and a set of WLs corresponding to the set of pages. Accordingly, each plane of the multi-plane block may have a set of pages and corresponding set of WLs. The WLs may be organized into multi-plane WLs spanning the planes of a multi-plane block. Each multi-plane WL may include one (1) WL from each plane of the multi-plane block. For example, a multi-plane WL may include a first WL from a first plane of a multi-plane block, a first WL from a second plane of the multi-plane block, a first WL from a third plane of the multi-plane block, and a first WL from a fourth plane of the multi-plane block. The first WL of the first plane may correspond to a first page of the first plane, the first WL of the second plane may correspond to a first page of the second plane, and so on. For a TLC multi-plane WL, each page (e.g., the first page of the first plane, the first page of the second plane) may include a lower page, a middle page, and an upper page. Accordingly, each WL of a TLC multi-plane WL may include three (3) pages. A total number of pages in a TLC multi-plane WL is a number of pages in each plane multiplied by a number of planes. For example, a TLC multi-plane WL of a four (4) plane NVM may include a total of twelve (12) pages.

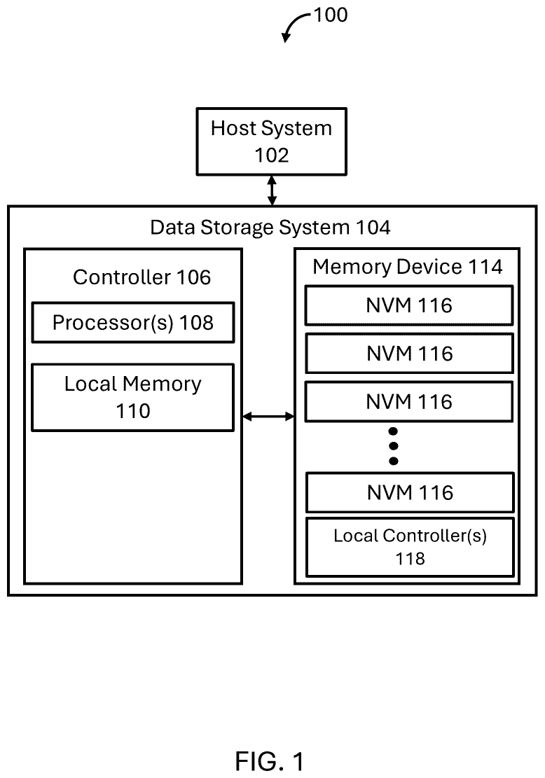

FIG. 1 illustrates an example system 100 including a host system 102 and a data storage system 104. The data storage system 104 may include a controller 106. The controller 106 may include a processor 108 and a local memory 110. The data storage system 104 may also include a memory device 114. The memory device 114 may be or otherwise include a NAND flash device, such as a solid state drive (SSD). The memory device 114 may include a plurality of NVM media 116 and one or more local controller(s) 118.

In various examples, a read or write request may be received from the host system 102 via a peripheral component interconnect express (PCIe) interface that connects the data storage system 104 to servers or CPUs. PCIe is a standardized interface for motherboard components. The controller 106 may use logical block addresses (LBAs) and physical block addresses (PBAs) to facilitate access for data storage in and retrieval from the NVM media 116. LBAs are an abstraction to allow the operating system to interact with the NVM media 116, and PBAs represent the actual hardware locations within the NVM media 116. To facilitate interacting with the NVM media 116, the controller 106 may create an entry or record that assigns an LBA to a PBA. To keep track of all such LBA-to-PBA assignments, the controller 106 may use a logical-to-physical (L2P) mapping table. The L2P table may be uploaded to the local memory 110 so that it can be more quickly accessed and updated by the controller 106. In various examples, the local memory 110 may include a synchronous dynamic random access memory (SDRAM), without limitation.

When a data request is received from the host system 102, the controller 106 references the L2P mapping table to determine the PBA within the NVM media 116 corresponding to a desired LBA. Once the PBA is determined, the controller 106 accesses the appropriate NVM media 116 to write or read the data. Access to the NVM media 116 may be via a flash physical (PHY) interface. The controller 106 may employ an error correction code (ECC) operation during encoding and decoding data to detect and correct errors and enhance data integrity. Additionally, the memory device 114 may support a direct memory access (DMA) operation enabling data to be written from the host system 102 directly to the NVM media 116 and read from the NVM media 116 directly to the host system 102. Certain commands may be issued to the controller 106 or the local controller(s) 118 using the host command layer, or non-volatile memory express management interface (NVMe-MI).

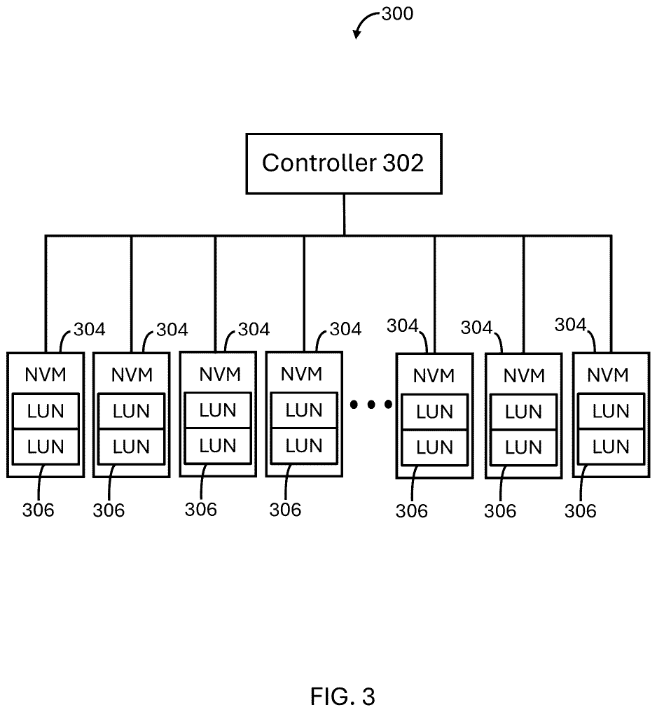

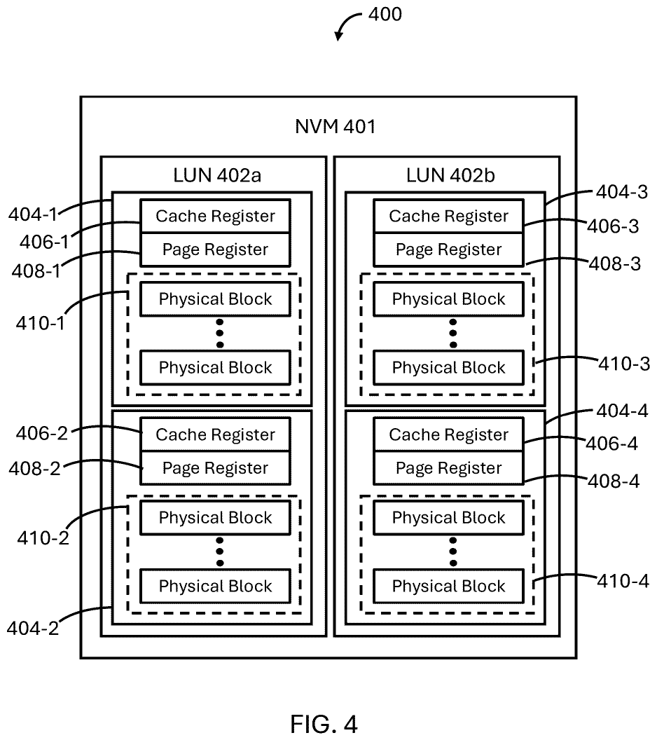

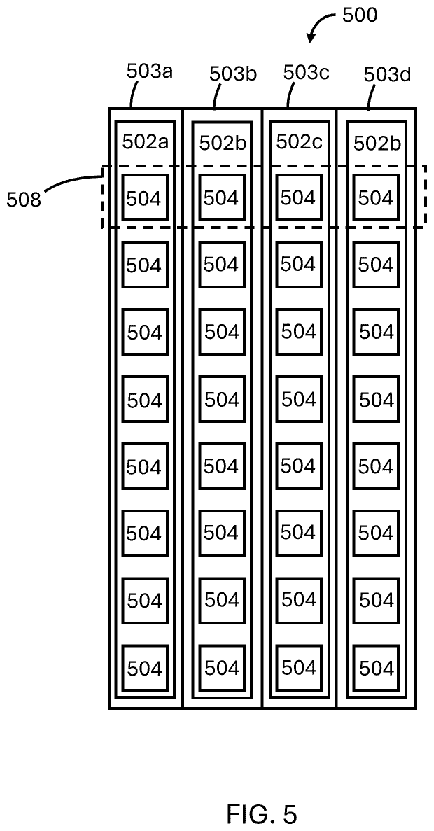

Each of the NVM media 116 may include a plurality of LUNs (e.g., the LUNs 306 of FIG. 3). Each LUN may include a plurality of planes (e.g., the planes 404-1, 404-2, 404-3, 404-4 of FIG. 4). Each plane may include a plurality of physical blocks (e.g., the physical blocks 410-1, 410-2, 410-3, and 410-4 of FIG. 4). Each block may include a set of pages (e.g., the pages 504 of FIG. 5). Each physical block may include a set of WLs corresponding to the pages. Respective ones of the physical blocks may be organized into a multi-plane block (e.g., the multi-plane block 500 of FIG. 5). Each multi-plane block may include one (1) physical block from each plane of one (1) LUN. Each multi-plane block may include a set of multi-plane WLs (e.g., the multi-plane WL 508 of FIG. 5). Each multi-plane WL may include corresponding WLs of the physical blocks included in a multi-plane block such that each multi-plane WL includes one (1) WL from each plane of the multi-plane block. User data may be written to the pages of a multi-plane WL.

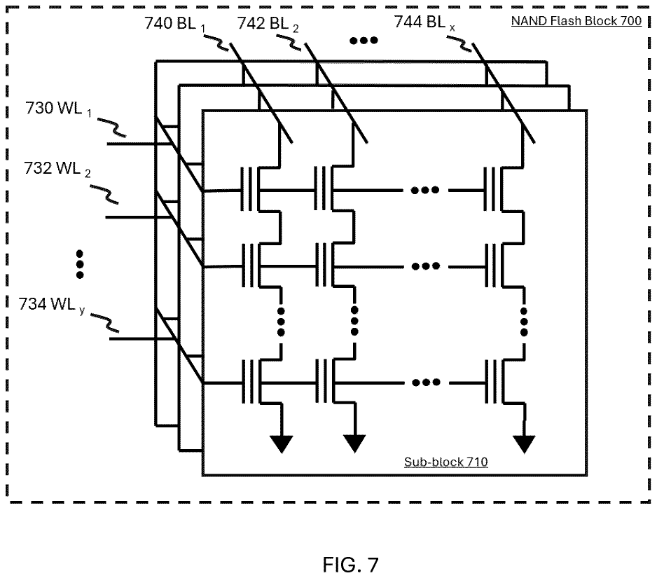

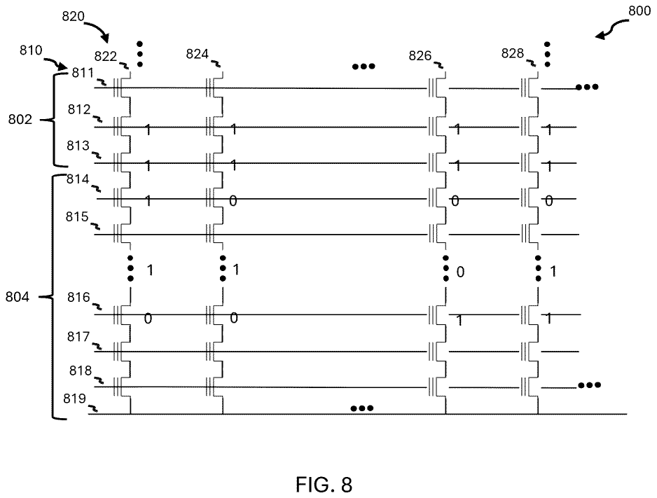

In various examples, the NAND Flash Block 700 of FIG. 7 and/or the block 800 of FIG. 8 may be representative of respective blocks included in the multi-plane blocks of FIG. 4. The NAND Flash Block 700 and/or the block 800 may also or alternatively at least partially comprise the NVM 116 of FIG. 1. Such blocks of a NAND flash device may be written to and/or read from repeatedly and/or continuously during ordinary use. Over time, the typical wear and tear incurred by the physical blocks (e.g., degradation to physical blocks resulting from repeated P/E cycles, instances of cross-temperature, etc.) can decrease performance of the devices. The present disclosure seeks to improve QoS of NAND flash devices by reducing errors (e.g., read errors) experienced during ordinary use.

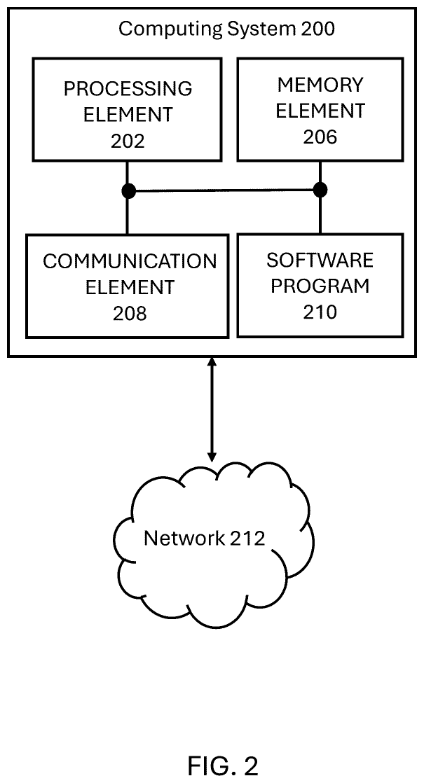

FIG. 2 illustrates a computing system 200 connected to a communication network 212. The computing system 200 may include at least one processing element 202, at least one memory element 206, a communication element 208, and a software program 210. In various examples, the computing system 200 may be a host system (e.g., the host system 102 of FIG. 1) and/or a data storage system (e.g., the data storage system 104 of FIG. 1), without limitation.

The software program 210 may be configured with instructions for performing and/or enabling performance of at least some of the steps set forth herein. In an embodiment, the software program 210 comprises instructions stored on computer-readable media of memory element 206. In various examples, the software program 210 may include instructions for performing operations of the controller 106 and/or local controller 118 discussed with reference to FIG. 1.

The communication network 212 generally allows communication between the computing system 200 and another computing device, such as between a remote host system (e.g., the host system 102), a local host system, and/or a data storage system (e.g., the data storage system 104 of FIG. 1), without limitation.

The communication network 212 may include the Internet, cellular communication networks, local area networks, metro area networks, wide area networks, cloud networks, plain old telephone service (POTS) networks, and the like, or combinations thereof. The communication network 212 may be wired, wireless, or combinations thereof and may include components such as modems, gateways, switches, routers, hubs, access points, repeaters, towers, and the like. The computing system 200 may, for example, connect to the communication network 212 either through wires, such as electrical cables or fiber optic cables, or wirelessly, such as RF communication using wireless standards such as cellular 2G, 3G, 4G or 5G, Institute of Electrical and Electronics Engineers (IEEE) 802.11 standards such as WiFi, IEEE 802.16 standards such as WiMAX, Bluetooth™, or combinations thereof.

The communication element 208 generally allows communication between the computing system 200 and the communication network 212. The communication element 208 may include signal or data transmitting and receiving circuits, such as antennas, amplifiers, filters, mixers, oscillators, digital signal processors (DSPs), and the like. The communication element 208 may establish communication wirelessly by utilizing radio frequency (RF) signals and/or data that comply with communication standards such as cellular 2G, 3G, 4G or 5G, Institute of Electrical and Electronics Engineers (IEEE) 802.11 standard, such as WiFi, IEEE 802.16 standard, such as WiMAX, Bluetooth™, or combinations thereof. In addition, the communication element 208 may utilize communication standards such as ANT, ANT+, Bluetooth™ low energy (BLE), the industrial, scientific, and medical (ISM) band at 2.4 gigahertz (GHz), or the like. Alternatively, or in addition, the communication element 208 may establish communication through connectors or couplers that receive metal conductor wires or cables, like Cat 6 or coax cable, which are compatible with networking technologies such as ethernet. In certain embodiments, the communication element 208 may also couple with optical fiber cables. The communication element 208 may respectively be in communication with the processing element 202 and/or the memory element 206.

The memory element 206 may include electronic hardware data storage components such as read-only memory (ROM), programmable ROM, erasable programmable ROM, random-access memory (RAM) such as static RAM (SRAM) or dynamic RAM (DRAM), solid state drives (SSDs), cache memory, hard disks, floppy disks, optical disks, flash memory, thumb drives, universal serial bus (USB) drives, or the like, or combinations thereof. In some embodiments, the memory element 206 may be embedded in, or packaged in the same package as, the processing element 202. The memory element 206 may include, or may constitute, a “computer-readable medium.” The memory element 206 may store the instructions, code, code segments, software, firmware, programs, applications, apps, services, daemons, or the like that are executed by the processing element 202. In an embodiment, the memory element 206 respectively store the software applications/program 210. The memory element 206 may also store settings, data, documents, sound files, photographs, movies, images, databases, and the like. In various examples, the memory element 206 may include a first memory component (e.g., the local memory 110 of FIG. 1) and one or more SSDs (e.g., the memory device 114 of FIG. 1).

The processing element 202 may include electronic hardware components such as processors. The processing element 202 may include digital processing unit(s). The processing element 202 may include microprocessors (single-core and multi-core), microcontrollers, digital signal processors (DSPs), field-programmable gate arrays (FPGAs), analog and/or digital application-specific integrated circuits (ASICs), or the like, or combinations thereof. The processing element 202 may generally execute, process, or run instructions, code, code segments, software, firmware, programs, applications, apps, processes, services, daemons, or the like. For instance, the processing element 202 may respectively execute the software applications/program 210. The processing element 202 may also include hardware components such as finite-state machines, sequential and combinational logic, and other electronic circuits that can perform the functions necessary for the operation of the current disclosure. The processing element 202 may be in communication with the other electronic components through serial or parallel links that include universal busses, address busses, data busses, control lines, and the like.

FIG. 3 illustrates an example data storage system 300 including a controller 302 and a plurality of NVM media 304. In various examples, the data storage system 300 may correspond to the data storage system 104 of FIG. 1, the controller 302 may correspond to the controller 106 of FIG. 1, and the NVM media 304 may correspond to the NVM media 116 of FIG. 1, without limitation. In various examples, the NVM media 304 may each include two LUNs 306. It would be appreciated by one of ordinary skill in the art that each NVM 304 may include more than two LUNs, without limitation. Each LUN 306 may correspond to a respective die of the NVM media 304. In various examples, the controller 302 may write incoming data to more than one NVM media 304 in parallel. The NVM media 304 may write incoming data to more than one LUN 306 in parallel. Each LUN 306 may include a set of multi-plane blocks.

FIG. 4 illustrates an example NVM media 400. The NVM 400 may correspond to the NVM media 116 of FIG. 1 and/or the NVM media 304 of FIG. 3, without limitation. The NVM media 400 may include a LUN 402a and a LUN 402b. The LUN 402a may include a plane 404-1 and a plane 404-2. The plane 404-1 may include a cache register 406-1, a page register 408-1, and physical blocks 410-1. The plane 404-2 may include a cache register 406-2, a page register 408-2, and physical blocks 410-2. The LUN 402b may include a plane 404-3 and a plane 404-4. The plane 404-3 may include a cache register 406-3, a page register 408-3, and physical blocks 410-3. The plane 404-4 may include a cache register 406-4, a page register 408-4, and physical blocks 410-4. It would be appreciated by one of ordinary skill in the art that the NVM media 400 may include more than two (2) die and each die may include more than two (2) planes. In various examples, the NVM media 400 may include two (2), four (4), eight (8), sixteen (16), twenty four (24), thirty two (32), or more die, without limitation. Each die may include, for example, four (4), six (6), eight (8), or more planes, without limitation.

When data is written to or retrieved from the LUN 402a or the LUN 402b, the data may be temporarily stored in one of the cache registers 406-1, 406-2, 406-3, 406-4 and/or the page registers 408-1, 408-2, 408-3, 408-4. The cache registers 406-1, 406-2, 406-3, 406-4 and the page registers 408-1, 408-2, 408-3, 408-4 may respectively have an equivalent data capacity of one page. Accordingly, data to be written to one page of one of the physical blocks 410-1 may be temporarily stored in the cache register 406-1 while data to be written to another page of one of the physical blocks 410-1 may be temporarily stored in the page register 408-1. Data being read from a page of one of the physical blocks 410-1 may be retrieved and temporarily stored in the page register 408-1 while data read from a page of another one of the physical blocks 410-1 may be transferred from the cache register 406-1 to a controller (e.g., the controller 106 of FIG. 1). Accordingly, the cache register and page register enable double buffering of data to reduce data programming and read times. Each page may include a plurality of cells. Data bits may be written to the plurality of cells on a WL-by-WL basis. Data may be erased from the plurality of cells on a physical block basis.

In various examples, a first set of multi-plane blocks may be formed across the planes 404-1, 404-2 of the LUN 402a and a second set of multi-plane blocks may be formed across the planes 404-3, 404-4 of the LUN 402b. Each multi-plane block of the first set of multi-plane blocks may include one (1) physical block from the plane 404-1 and one (1) physical block from the plane 404-2. Each multi-plane block of the second set of multi-plane blocks may include one (1) physical block from the plane 404-3 and one (1) physical block from the plane 404-4. For example, a first multi-plane block may include a first one of the physical blocks 410-1 and a first one of the physical blocks 410-2. A second multi-plane block may include a first one of the physical blocks 410-3 and a first one of the physical blocks 410-4.

Each multi-plane block may include a multi-plane WL (e.g., the multi-plane WL 508 of FIG. 5). Accordingly, each set of multi-plane blocks may include a corresponding set of multi-plane WLs. For example, a first multi-plane WL may include a WL of one of the physical blocks 410-1 and a WL of one of the physical blocks 410-2. A second multi-plane WL may include a WL from one of the physical blocks 410-3 and a WL of one of the physical blocks 410-4. In an example, a multi-plane WL may include one (1) WL from each plane 404-1, 404-2, 404-3, 404-4. A multi-plane block may include one (1) physical block 410-1 from the plane 404-1, one (1) physical block 410-2 from the plane 404-2, one (1) physical block 410-3 from the plane 404-3, and one (1) physical block 410-4 from the plane 404-4. The WLs or physical blocks that make up a multi-plane WL or multi-page block may or may not be in a same location of each plane of a corresponding one of the LUNs 402a, 402b.

FIG. 5 illustrates a multi-plane block 500 of an NVM (e.g., the NVM 116 of FIG. 1). The multi-plane block may include physical blocks 502a, 502b, 502c, 502d. The physical blocks 502a, 502b, 502c, 502d may be included in a set of planes 503a, 503b, 503c, 503d. Each physical block 502a, 502b, 502c, 502d may include a set of pages 504. A multi-plane WL 508 may be formed to include a page 504 of each physical block 502a, 502b, 502c, 502d.

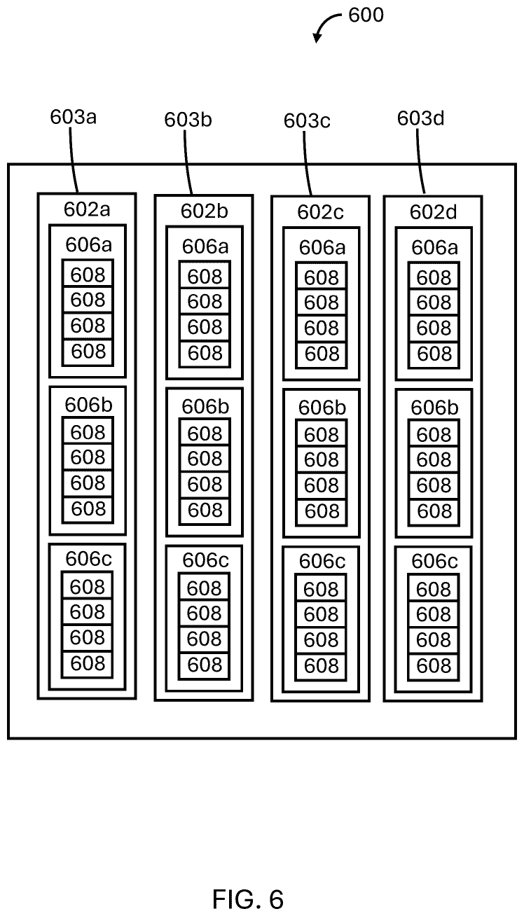

FIG. 6 illustrates a multi-plane WL 600 of a multi-plane block (e.g., the multi-plane block 500 of FIG. 5). The multi-plane WL 600 may include pages 602a, 602b, 602c, 602d. The pages 602a, 602b, 602c, 602d may be included in a set of physical blocks 603a, 603b, 603c, 603d that make up the multi-plane block. The pages 602a, 602b, 602c, 602d may be TLC pages that include TLC cells. Accordingly, each of the pages 602a, 602b, 602c, 602d may include an upper page 606a, a middle page 606b, and a lower page 606c. It would be appreciated by one of ordinary skill in the art that the pages 602a, 602b, 602c, 602d could include SLC pages, MLC pages, TLC, QLC pages, and/or PLC pages without departing from the spirit of the present disclosure. A plurality of data frames 608 may be stored in each of the upper pages 606a, middle pages 606b, and lower pages 606c.

Through hardware, software, firmware, or various combinations thereof, any of the processing elements (e.g., the controller 106 and/or local controller(s) 118 of FIG. 1, the processing element 202 of FIG. 2, and/or the controller 302 of FIG. 3) may—alone or in combination with other processing elements-be configured to perform the operations of embodiments of the present disclosure. The embodiments described herein in connection with the attached drawing figures are intended to describe aspects of the disclosure in sufficient detail to enable those skilled in the art to practice the disclosure. Other embodiments can be utilized and changes can be made without departing from the scope of the present disclosure. The system may include additional, less, or alternate functionality and/or device(s), including those discussed elsewhere herein. The above and below detailed description is, therefore, not to be taken in a limiting sense. The scope of the present disclosure is defined only by the appended claims, along with the full scope of equivalents to which such claims are entitled, unless otherwise expressly stated and/or readily apparent to those skilled in the art from the description.

FIG. 7 illustrates an example NAND Flash Block 700 that includes a plurality of sub-blocks (e.g., Sub-block 710). In some examples, NAND Flash Block 700 may be included in one or more of the NVM Media 116 of FIG. 1 and/or may be included in one or more of the blocks comprising the multi-plane blocks included in NVM media 400 of FIG. 4. Sub-block 710 and each additional sub-block included in the plurality of sub-blocks of NAND Flash Block 700 are arranged in a three-dimensional (3D) structure, and each sub-block includes a plurality of WLs (e.g., the WLs: WL₁ 730, WL₂ 732, and WL_{y} 734) and a plurality of BLs (e.g., the BLs: BL₁ 740, BL₂ 742, and BLₓ 744). At each intersection or junction of a WL and a BL is a transistor (or “cell”). In some examples, floating-gate transistors are utilized as the cells included in NAND Flash Block 700.

As depicted in FIG. 7, WL₁ 730 is connected to the gates of cells included in the top-most row in Sub-block 710. Further, although not depicted explicitly, WL₁ 730 is also connected to the gates of the cells in the top-most row of cells included in each additional sub-block of NAND Flash Block 700. Similarly, WL₂ 732 connects the gates of cells included in the row of cells that is second from the top in Sub-block 710 as well as gates of cells included in each row of cells that is the second from the top in each additional sub-block included in NAND Flash Block 700. WL_{y} likewise connects the gates of cells included in the bottom-most rows of cells included in Sub-block 710 and the additional sub-blocks of NAND Flash Block 700.

Each of the illustrated bitlines BL₁ 740, BL₂ 742, and BLₓ 744 connects a vertically-aligned column of cells by connecting respective drain and source terminals of adjacent cells (e.g., in keeping with the discussion above, cells which are physically closest to each other within a logical grouping such as the sub-block 710, such as where a terminal of the cell at the intersection of WL₁ 730 and BL₁ 740 connects to a terminal of the cell at the intersection of WL₂ 732 and BL₁ 740), except that the drains of cells included in WL_{y} 734 may be connected to “ground.” One of ordinary skill will appreciate that any number of WLs (WL_{y}) and BLs (BLₓ) may be included in the NAND Flash Block 700 within the scope of the present disclosure.

FIG. 8 illustrates an example arrangement of WLs and BLs comprising a block 800, which may be included in a NAND flash device (e.g., the Data Storage System 104 and/or the Memory Device 114 of FIG. 1). The arrangement of WLs and BLs comprising the block 800 may either comprise a NAND flash block (e.g., NAND Flash Block 700 of FIG. 7) or a sub-block (e.g., Sub-block 710 of FIG. 7) depending on the configuration of the data storage system (e.g., Data Storage System 104 of FIG. 1) in which the block 800 is included.

As illustrated, the block 800 includes two main sub-sections: sub-section 802 and sub-section 804. The block 800 includes a plurality of WLs 811, 812, 813, 814, 815, 816, 817, and 818, (collectively, “the wordlines 810” or “the WLs 810”) along with a plurality of BLs 822, 824, 826, and 828 (collectively “the bitlines 820” or “the BLs 820”). The block 800 may also include a ground or source line or plane 819.

In some examples, the state of the block 800 may be either fully closed, partially open, or completely open, corresponding respectively, for example, to fully programmed, partially programmed, or completely unprogrammed states. In some examples, block 800 is partially programmed, with the sub-section 802 being an unprogrammed portion and the sub-section 804 being a portion programmed with randomly distributed bits. The WLs of the unprogrammed sub-section 802 may be in an erase state. The WL 814 is the last-written WL (LWL) of the sub-section 804. The WLs of the block which are not selected for a read operation may be described as unselected WLs (UWLs).

In this or similar configurations of the block 800, a read operation having LWL 814 selected may be performed by applying a read voltage (or “Vread”) to LWL 814, and by applying a default pass-through voltage (Vpassr) to the UWLs of the block 800 (e.g., WLs 811-813 and 815-818). Generally, a pass-through voltage is a voltage that passes directly through a circuit, from input to output, as if there were zero (0) impedance in the circuit (e.g., as if a wire were shorting the input to the output). A pass-through voltage may be applied to unselected WLs of a block (e.g., the block 800) of a NAND flash device that is being subjected to a read operation. Application of the pass-through voltage may ensure the unselected WLs are “ON,” or working/operating at the value of the applied pass-through voltage. This may enable data from one or more cells of a selected WL (e.g., the WL of the block that is being read and that is receiving a read voltage, Vread—in this case LWL 814) to be transmitted via the BLs of the block being read. The pass-through voltage applied to a block being read is typically greater than Vread.

However, in cases where a block is partially programmed (e.g., is at least partially closed)—such as block 800—applying a typical (or default) Vpassr to all the UWLs 811-813 and 815-818 may lead to read errors. Various examples of the present disclosure seek to address such error(s) by subjecting at least one UWL—e.g., at least one of the two (2) UWLs that are adjacent the LWL 814 (e.g., UWLs 813, 815)—to an adjusted Vpassr, as discussed in more detail below. In the example illustrated in FIG. 8, the adjusted Vpassr may be applied at least to UWL 813—that is, the UWL which is unprogrammed and adjacent the LWL—to reduce read errors.

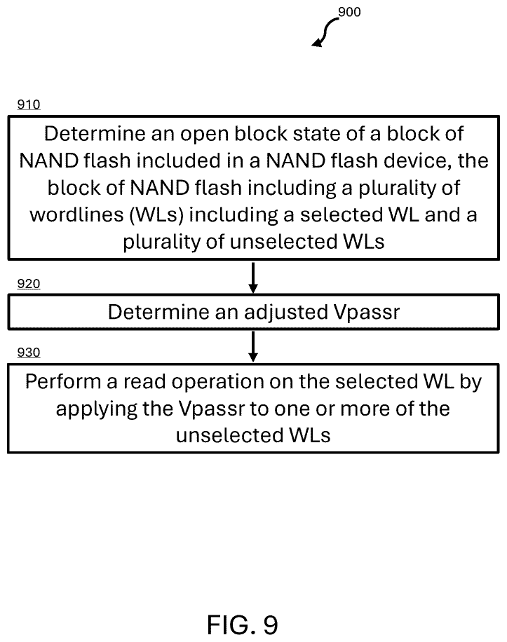

FIG. 9 illustrates a computer-implemented method 900 for reducing read errors in a NAND flash device. The steps may be performed in the order shown in FIG. 9, or they may be performed in a different order. Furthermore, some steps may be performed concurrently as opposed to sequentially. In addition, some steps may be optional.

The method 900 may be performed by a controller (e.g., the controller 106 and/or controller(s) 118 of FIG. 1) of a data storage system (e.g., the data storage system 104 of FIG. 1). The method 900 may operate on a block of an NVM described in more detail above in connection with FIGS. 1-8. However, a person having ordinary skill will appreciate that responsibility for all or some of the operations described herein may be distributed differently among such devices or other computing devices without departing from the spirit of the present disclosure.

The controller may manage storage and retrieval of data to and from a memory device (e.g., the memory device 114 of FIG. 1). The controller may receive read and write requests from a host system (e.g., the host system 102 of FIG. 1). Upon receiving a write request, the controller may facilitate writing data received from the host system to the memory device. Upon receiving a read request, the controller may facilitate reading of data from the memory device and communication of the data to the host system, as discussed in more detail below.

One or more computer-readable medium(s) may also be provided. The computer-readable medium(s) may include one or more executable programs stored thereon, such as firmware programs, wherein the program(s) instruct one or more processing elements to perform all or certain of the steps or operations outlined herein. The program(s) stored on the computer-readable medium(s) may instruct the processing element(s) to perform additional, fewer, or alternative actions, including those discussed elsewhere herein.

At operation 910, one or more blocks of NAND flash memory media are determined to be in an open block state. Generally, a block (e.g., the block 800 of FIG. 8) of memory is considered to be in an “open block state” when the block is in an at least partially erased state, meaning at least a portion of the cells included therein are available to be programmed or are presently unprogrammed.

The block of NAND flash may include a plurality of WLs including a selected WL and an unselected WL (UWL) adjacent the selected WL. In various examples, the selected WL may be a last-written one of the plurality of WLs (LWL) of the block (e.g., LWL 814 of FIG. 8), and an adjacent UWL (e.g., UWL 813) may be unprogrammed. Further, the plurality of WLs may include a second UWL adjacent to the selected WL (e.g., UWL 815). The second UWL may be programmed. In various examples, performing the read operation may include applying the adjusted Vpassr to the second adjacent UWL. In various examples, the plurality of WLs may include one or more additional UWLs which are programmed, and/or one or more additional UWLs which are unprogrammed.

At operation 920, an adjusted pass-through voltage (Vpassr) is determined. In various examples, the adjusted Vpassr may be determined responsive to determining that the block of NAND flash is in an open block state. Additionally and/or alternatively, the determination of the adjusted Vpassr may be based at least in part on one or more UWLs being adjacent the selected WL, or LWL, (again, as the UWLs 813 and 815 are each adjacent to the selected WL 814 of FIG. 8). In various examples, determining the adjusted Vpassr includes determining one or more of: a number of program/erase (P/E) cycles performed by the block; an amount of the block which is open; an amount of the block which is in an erase state; a temperature of the block in connection with a program operation for the block; a temperature of the block in connection with the read operation; a physical location of the selected WL within the block; or a physical location of the block within the NAND flash device. In accordance with examples of the present disclosure, the amount of the block which is open may correspond to a percentage of the plurality of WLs included in the block that are unwritten.

Determining the adjusted Vpassr may also include one or more of: decreasing a default Vpassr more where a high amount of the block is open relative to a low amount of the block being open; decreasing a default Vpassr more where a lower number of P/E cycles have been performed by the block relative to a higher number of P/E cycles having been performed by the block; and determining an offset value for application to the default Vpassr.

The relationship between the dependent variable (i.e., the value of adjusted Vpassr) and the independent variable (e.g., degree of openness of or number of P/E cycles performed by the block) discussed above may be linear or non-linear without departing from the spirit of the present disclosure. For example, the default Vpassr may be linearly reduced by a consistent unit size (e.g., a delta_Vpassr) for each incremental change in block openness (e.g., expressed as a percentage of total), or for each incremental change in number of P/E cycles of the block. Alternatively, Vpassr may be non-linearly changed in accordance with incremental increases or decreases of respective independent variables.

As a non-limiting example, a block of NAND flash may include two hundred (200) WLs and may be subject to a default Vpassr of eight volts (8V), e.g., for performing a read operation on the block. Initially, the block of NAND flash may be only 5% written (e.g., is 95% open). Subsequently, the block of NAND flash may be 90% written (e.g., is 10% open). The BLs of the block of NAND flash may exhibit greater resistivity when the block is less open (e.g., 10% open), relative to when the block is more open (e.g., 90% open). According to various examples, the adjusted Vpassr may represent a greater adjustment (i.e., a greater delta_Vpassr) of the default Vpassr where the block is in the more open state relative to the less open state. For instance, the default Vpassr may be reduced by one hundred millivolts (100 mV) when performing a read operation on a block that is 90% open (resulting in the block of NAND flash receiving an adjusted Vpassr of 7.9V). By comparison, the default Vpassr may have only been reduced by a delta_Vpassr of 50 mV (resulting in the block receiving an adjusted Vpassr of 7.95V) when being read while only 10% open.

As another non-limiting example, a new block of NAND flash (e.g., one that has yet to undergo any program-erase, or “P/E,” cycles) may be subject to a default Vpassr of 8V. An initial delta_Vpassr may be relatively large, resulting in significantly lower adjusted Vpassr than the default Vpassr for a new block, and the delta_Vpassr may decrease with the number of P/E cycles performed on/experienced by the block. For instance, after the first one hundred (100) P/E cycles performed on/experienced by the block, a first adjusted Vpassr may be determined and applied, where the first adjusted Vpassr may reflect a delta_Vpassr of 100 mV, i.e., the adjusted Vpassr may be 7.9V. Correspondingly, after undergoing one thousand (1,000) total P/E cycles, an adjusted Vpassr of 7.91V may be applied to perform a read operation on the block of NAND flash. In other words, following application of an initial offset of or delta_Vpassr applied to a default Vpassr corresponding to the new block, the delta_Vpassr may be decreased as a number of P/E cycles performed on/experienced by a block of NAND flash increases.

In addition to adjustments to delta_Vpassr made over time (i.e., as a block's state changes, including according to the discussion above), multiple delta_Vpassrs, and/or the default Vpassr, may be determined and utilized in any combination during a single read operation. In various examples, additional adjusted Vpassrs may be determined for application to UWLs other than the first UWL, such as the second UWL discussed above and/or others of the plurality of UWLs of the block. The additional adjusted Vpassrs (including a second, third, fourth, etc. adjusted Vpassr) may be determined based on factors described above for determination of the (first) adjusted Vpassr. Accordingly, the second and subsequent additional adjusted Vpassrs may vary from the first adjusted Vpassr based at least in part on degree of removal from (or distance from) the selected LWL. Additionally and/or alternatively, the second and subsequent additional adjusted Vpassrs may vary from the first adjusted Vpassr based at least in part on a degree of removal (or distance) of the block of NAND flash receiving the adjusted Vpassr(s) from sense amplifier(s) included in the NAND flash device.

At 930, a read operation may be performed on the selected LWL by applying the adjusted Vpassr to one or more of the UWLs. In various examples, the UWL(s) may be in an erase state during the read operation and may include one or both of the UWLs that are adjacent the LWL.

In various examples, performing the read operation at 930 may also include applying the adjusted Vpassr to: one or more of the plurality of UWLs other than the first UWL, such as the second UWL, additional unprogrammed UWLs (e.g., all remaining unprogrammed UWLs of the block) and/or additional programmed UWLs (e.g., all remaining programmed UWLs of the block), in any combination.

Application of the adjusted Vpassr may include issuing, via a controller included in the NAND flash device (e.g., the Controller 106 included in Data Storage System 104 of FIG. 1), a command to adjust a default Vpassr by the determined offset value (e.g., the delta_Vpassr described above). The command may be issued to a component of the NAND flash device configured for determining and/or applying pass-through voltages to WLs in connection with read operations. The command may also include instructions to apply additional offset values to the default Vpassr corresponding to respective additional adjusted Vpassrs, also in accordance with the discussions above and below.

The remaining WLs of the block (e.g., those other than the selected LWL its adjacent first UWL and, optionally, the second adjacent UWL discussed above) may be subjected to the default Vpassr in connection with the read operation. However, in accordance with various examples of the present disclosure and as noted above, the adjusted Vpassr, or one or more other or additional adjusted Vpassrs, may also/alternatively be applied during the read operation to all or some of the remaining UWLs, including the remaining unprogrammed UWLs. For example, the first adjusted Vpassr may additionally be applied to the next unprogrammed UWL adjacent the unprogrammed UWL which is adjacent the selected LWL. In various examples, a second adjusted Vpassr may alternatively be applied to the next unprogrammed UWL, such as a second adjusted Vpassr which is reduced to a lesser degree than the first adjusted Vpassr (i.e., is closer in value to the default Vpassr). One of ordinary skill will appreciate that a plurality of additional adjusted Vpassrs may be applied to subsets of the UWLs in connection with the read operation within the scope of the present invention. Notwithstanding the possibility of applying adjusted Vpassrs to others of the UWLs, the default Vpassr may be applied to one or more of the UWLs for the read operation.

In a more particular example, the first adjusted Vpassr may be applied to the next unprogrammed UWL of the plurality of WLs, and the default Vpassr may be applied to remaining ones of the UWLs. Accordingly, the next unselected WL may (i) be adjacent the UWL, and (ii) be unprogrammed.

As previously mentioned, in each of the examples above as well as those discussed hereunder, one of ordinary skill will appreciate that a plurality of UWLs may be present in the described block(s) of NAND flash, even if “an” (e.g., a singular) unselected WL (or UWL) is expressly referenced in the disclosure or a claim. It will be further appreciated by one of ordinary skill that, in each of the examples above as well as those discussed hereunder, the adjusted Vpassr and/or a plurality of adjusted Vpassrs (e.g., the claimed adjusted Vpassr and one or more additional adjusted Vpassrs) may be applied to the recited UWL and/or other, additional UWLs in the described block(s) of NAND flash (e.g., one or both adjacent UWLs and/or other UWLs), even if only a single adjusted Vpassr is expressly referenced. Further, another Vpassr(s) (e.g., one or more default Vpassr(s)) may be applied individually and/or in combination with the various combinations of the one or more adjusted Vpassrs to the various combinations of UWLs described above, and as discussed in more detail elsewhere herein.

To reiterate, Vread is applied to the selected LWL, the first adjusted Vpassr may be applied to the unprogrammed UWL adjacent the selected LWL, and some combination of the first adjusted Vpassr, one or more additional adjusted Vpassrs and/or the default Vpassr may be applied to the remaining WLs of the block, to perform the read operation. Alternatively, Vread is applied to the selected LWL, the first adjusted Vpassr may be applied to the programmed UWL adjacent the selected LWL, and some combination of the first adjusted Vpassr, one or more additional adjusted Vpassrs and/or the default Vpassr may be applied to the remaining WLs of the block, to perform the read operation. Embodiments of the present disclosure thus provide improved QoS of and/or reduce (read) errors in a NAND flash device. Several more particular examples are provided in the discussion below.

In various examples, a block (or sub-block) of NAND flash memory, such as NAND Flash Block 700, the block 800, or the sub-block 710, may include any number (N) of WLs. These WLs may be numbered sequentially, starting at wordline zero (0), or “WL₀,” and ending at WL_{N-1}. For instance, if a block of NAND flash were to include two hundred and one (201) WLs, the WLs in this block of NAND flash would range from WL₀ through WL₂₀₀. The LWL of this block (e.g., LWL 814 of FIG. 8) of NAND flash may be the wordline WLₙ, where 0<n<N. The WLs adjacent the LWL WLₙ may be represented as WLₙ₋₁ and WL₊₁. For example, ‘n’ may equal 50, making WL₅₀ the LWL of this block and WL₄₉ and WL₅₁ the WLs adjacent the LWL (which, again, is WL₅₀). The wordline WLₙ may be a selected WL (e.g., selected as the target of a read operation that is to be performed by the NAND flash device, or already receiving a read voltage (Vread)). All other WLs included in the block (e.g., WL₀-WLₙ₋₁ and WLₙ₊₁-WL_{N}) may be unselected WLs. The WLs WL₀-WLₙ₋₁ may be programmed (or “closed”) and the WLs WLₙ₊₁-WL_{N} may be unprogrammed (or “open”). In these examples, all the unselected WLs (e.g., WL₀-WLₙ₋₁ and WLₙ₊₁-WL_{N}) may receive the same adjusted Vpassr determined based at least in part on the determination that the block is partially programmed or open (and/or a corresponding degree or proportion of openness).

In various other examples, the block of NAND flash may be completely closed (e.g., all of the WLs from WL₀-WL_{N} are programmed). In these embodiments, WLₙ may still be selected to receive Vread. However, the remaining, unselected WLs (e.g., WL₀-WLₙ₋₁ and WLₙ₊₁-WL_{N}) may receive the same adjusted Vpassr which, in this case, is also determined based at least in part on the determination that the block is completely closed (and/or a corresponding degree or proportion of openness), but which is different than the adjusted Vpassr received by the unselected WLs in the example of the preceding paragraph, owing at least in part to the difference in degree of openness.

In various examples, WLₙ may be selected for a read operation, the WLs WL₀-WLₙ₋₂ and WLₙ₊₂-WL_{N} may receive a first adjusted Vpassr, and the WLs WLₙ₋₁ and WLₙ₊₁ may receive a second adjusted Vpassr.

In various examples, WLₙ may be selected for a read operation, the WLs WL₀-WLₙ₋₁ may receive a first adjusted Vpassr, and the WLs WLₙ₊₁-WL_{N} may receive a second adjusted Vpassr.

In various examples, WLₙ may be selected for a read operation, the WLs WLₙ₋₁ and WLₙ₊₁ may receive a first adjusted Vpassr, and the WLs WL₀-WLₙ₋₂ and WLₙ₊₂-WL_{N} may receive a second adjusted Vpassr.

In any of the above-mentioned examples, the WLs WLₙ₊₁ and WLₙ₊₁ may receive different Vpassrs.

Applying a Vpassr (e.g., a default Vpassr, a first adjusted Vpassr, a second adjusted Vpassr, etc.) closer to the selected WL (e.g., the selected WL/LWL WLₙ) may have a greater impact on the read operation being performed on the selected WL. Accordingly, applying one or more adjusted Vpassr(s) to the WLs WLₙ₋₂, WLₙ₋₁, WLₙ₊₁, and/or WLₙ₊₂ is generally preferable. However, application of one or more adjusted Vpassr(s) to UWLs or groups of UWLs that are further away from the selected WL is within the scope of the present disclosure, as discussed above. Blocks of varying degrees of openness than those described in the examples above are also within the ambit of the present disclosure.

### Feature Combinations

According to various examples of the present disclosure, computer-implemented methods for reducing errors in a NAND flash device may include: determining an open block state of a block of NAND flash included in the NAND flash device, the block of NAND flash including a plurality of wordlines (WLs) including a selected WL and an unselected WL; responsive to determining that the block of NAND flash is in an open block state, determining an adjusted Vpassr; and performing a read operation on the selected WL by applying the adjusted Vpassr to the unselected WL.

In combination with any of the previous examples, the unselected WL may be adjacent to the selected WL, the plurality of WLs may include a second unselected WL adjacent to the selected WL, and performing the read operation may include applying the adjusted Vpassr to the second unselected WL.

In combination with any of the previous examples, determining the adjusted Vpassr may include determining one or more of: a number of P/E cycles performed by the block; an amount of the block which is open; an amount of the block which is in an erase state; a temperature of the block in connection with a program operation for the block; a temperature of the block in connection with the read operation; a physical location of the selected WL within the block; or a physical location of the block.

In combination with any of the previous examples, determining the adjusted Vpassr may at least in part include decreasing a default Vpassr more where a high amount of the block is open relative to a low amount of the block being open.

In combination with any of the previous examples, performing the read operation may include applying the adjusted Vpassr to one or more of the plurality of WLs other than the unselected WL.

In combination with any of the previous examples, determining the adjusted Vpassr may at least in part include decreasing a default Vpassr more where a lower number of P/E cycles have been performed by the block relative to a higher number of P/E cycles having been performed by the block.

In combination with any of the previous examples, determining the adjusted Vpassr may at least in part include determining an offset value for application to a default Vpassr.

In combination with any of the previous examples, applying the adjusted Vpassr to the unselected WL may include issuing, by a controller included in the NAND flash device, a command to adjust a default Vpassr by an offset value to a component of the NAND flash device.

In combination with any of the previous examples, the selected WL may be a last-written one of the plurality of WLs, the unselected WL may be unprogrammed, the plurality of WLs may include one or more unselected programmed WLs, and the plurality of WLs may include one or more unprogrammed WLs in addition to the unselected WL.

In combination with any of the previous examples, performing the read operation may include applying the adjusted Vpassr to one or more additional unprogrammed WLs.

In combination with any of the previous examples, performing the read operation may include: applying an adjusted Vpassr to a next unselected WL of one or more additional unprogrammed WLs, the next unselected WL being adjacent an unselected WL; applying a default Vpassr to one or more unselected programmed WLs; and applying the default Vpassr to those of the one or more additional unprogrammed WLs other than the next unselected WL.

In combination with any of the previous examples, the determination of the adjusted Vpassr may be based at least in part on an unselected WL being adjacent a selected WL, and wherein a plurality of WLs includes a next unselected WL of one or more additional unprogrammed WLs, the next unselected WL having a position adjacent the unselected WL, further comprising: determining, based at least in part on the position of the next unselected WL, a second adjusted Vpassr, wherein performing the read operation includes applying the second adjusted Vpassr to the next unselected WL.

In combination with any of the previous examples, the unselected WL may be in an erase state during the read operation.

According to various examples of the present disclosure, non-transitory computer-readable media having instructions stored thereon are provided which, when executed by one or more processors, cause the one or more processors to perform the steps comprising the computer-implemented method described above.

### General Considerations

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

Certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various embodiments, computer hardware, such as a processing element, may be implemented as special purpose or as general purpose. For example, the processing element may comprise dedicated circuitry or logic that is permanently configured, such as an application-specific integrated circuit (ASIC), or indefinitely configured, such as an FPGA, to perform certain operations. The processing element may also comprise programmable logic or circuitry (e.g., as encompassed within a general-purpose processor or other programmable processor) that is temporarily configured by software to perform certain operations. It will be appreciated that the decision to implement the processing element as special purpose, in dedicated and permanently configured circuitry, or as general purpose (e.g., configured by software) may be driven by cost and time considerations.

Accordingly, the term “processing element” or equivalents should be understood to encompass a tangible entity, be that an entity that is physically constructed, permanently configured (e.g., hardwired), or temporarily configured (e.g., programmed) to operate in a certain manner or to perform certain operations described herein. Considering embodiments in which the processing element is temporarily configured (e.g., programmed), each of the processing elements need not be configured or instantiated at any one instance in time. For example, where the processing element comprises a general-purpose processor configured using software, the general-purpose processor may be configured as respective different processing elements at different times. Software may accordingly configure the processing element to constitute a particular hardware configuration at one instance of time and to constitute a different hardware configuration at a different instance of time.

Computer hardware components, such as communication elements, memory elements, processing elements, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In embodiments in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processing elements that are temporarily configured (e.g., by software) or permanently configured to perform the relevant operations. Whether temporarily or permanently configured, such processing elements may constitute processing element-implemented modules that operate to perform one or more operations or functions. The modules referred to herein may, in some example embodiments, comprise processing element-implemented modules.

Similarly, the methods or routines described herein may be at least partially processing element-implemented. For example, at least some of the operations of a method may be performed by one or more processing elements or processing element-implemented hardware modules. The performance of certain of the operations may be distributed among the one or more processing elements, not only residing within a single machine, but deployed across a number of machines. In some example embodiments, the processing elements may be located in a single location (e.g., within a home environment, an office environment or as a server farm), while in other embodiments the processing elements may be distributed across a number of locations.

Unless specifically stated otherwise, discussions herein using words such as “processing,” “computing,” “calculating,” “determining,” “presenting,” “displaying,” or the like may refer to actions or processes of a machine (e.g., a computer with a processing element and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

Although the invention has been described with reference to the embodiments illustrated in the attached drawing figures, it is noted that equivalents may be employed and substitutions made herein without departing from the scope of the invention as recited in the claims.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

What is claimed is:

1. A computer-implemented method for reducing errors in a NAND flash device, the method comprising:
determining an open block state of a block of NAND flash included in the NAND flash device, the block of NAND flash including a plurality of wordlines (WLs) including a selected WL and an unselected WL;
responsive to determining that the block of NAND flash is in an open state, determining an adjusted Vpassr; and
performing a read operation on the selected WL by applying the adjusted Vpassr to the unselected WL.

2. The computer-implemented method of claim 1, wherein:
the unselected WL is adjacent to the selected WL,
the plurality of WLs includes a second unselected WL adjacent to the selected WL,
performing the read operation includes applying the adjusted Vpassr to the second unselected WL.

3. The method of claim 1, wherein determining the adjusted Vpassr includes determining one or more of: a number of P/E cycles performed by the block; an amount of the block which is open; an amount of the block which is in an erase state; a temperature of the block in connection with a program operation for the block; a temperature of the block in connection with the read operation; a physical location of the selected WL within the block; or a physical location of the block.

4. The computer-implemented method of claim 1, wherein determining the adjusted Vpassr at least in part includes decreasing a default Vpassr more where a high amount of the block is open relative to a low amount of the block being open.

5. The computer-implemented method of claim 1, wherein performing the read operation includes applying the adjusted Vpassr to one or more of the plurality of WLs other than the unselected WL.

6. The computer-implemented method of claim 1, wherein determining the adjusted Vpassr at least in part includes decreasing a default Vpassr more where a lower number of P/E cycles have been performed by the block relative to a higher number of P/E cycles having been performed by the block.

7. The computer-implemented method of claim 1, wherein determining the adjusted Vpassr at least in part includes determining an offset value for application to a default Vpassr.

8. The computer-implemented method of claim 7, wherein applying the adjusted Vpassr to the unselected WL includes issuing, by a controller included in the NAND flash device, a command to adjust the default Vpassr by the offset value to a component of the NAND flash device.

9. The method of claim 1, wherein:
the selected WL is a last-written one of the plurality of WLs,
the unselected WL is unprogrammed,
the plurality of WLs includes one or more unselected programmed WLs,
the plurality of WLs includes one or more unprogrammed WLs in addition to the unselected WL.

10. The computer-implemented method of claim 9, wherein performing the read operation includes applying the adjusted Vpassr to the one or more additional unprogrammed WLs.

11. The computer-implemented method of claim 9, wherein performing the read operation includes:
applying the adjusted Vpassr to a next unselected WL of the one or more additional unprogrammed WLs, the next unselected WL being adjacent the unselected WL,
applying a default Vpassr to the one or more unselected programmed WLs,
applying the default Vpassr to those of the one or more additional unprogrammed WLs other than the next unselected WL.

12. The computer-implemented method of claim 9, wherein the determination of the adjusted Vpassr is based at least in part on the unselected WL being adjacent the selected WL and wherein the plurality of WLs includes a next unselected WL of the one or more additional unprogrammed WLs, the next unselected WL having a position adjacent the unselected WL, further comprising:
determining, based at least in part on the position of the next unselected WL, a second adjusted Vpassr,
wherein performing the read operation includes applying the second adjusted Vpassr to the next unselected WL.

13. The computer-implemented method of claim 1, wherein the unselected WL is in an erase state during the read operation.

14. Non-transitory computer-readable media of a NAND flash device controller, the non-transitory computer-readable media having instructions embodied thereon which, when executed by one or more processors, cause the one or more processors to:
determine an open block state of a block of NAND flash included in a NAND flash device, the block of NAND flash including a plurality of wordlines (WLs) including a selected WL and an unselected WL;
responsive to determining that the block of NAND flash is in an open state, determine an adjusted Vpassr; and
perform a read operation on the selected WL by applying the adjusted Vpassr to the unselected WL.

15. The non-transitory computer-readable media of claim 14, wherein:
the unselected WL is adjacent to the selected WL,
the plurality of WLs includes a second unselected WL adjacent to the selected WL,
performing the read operation includes applying the adjusted Vpassr to the second unselected WL.

16. The non-transitory computer-readable media of claim 14, wherein the adjusted Vpassr is determined based on one or more of: a number of P/E cycles performed by the block; an amount of the block which is open; an amount of the block which is in an erase state; a temperature of the block in connection with a program operation for the block; a temperature of the block in connection with the read operation; a physical location of the selected WL within the block; or a physical location of the block.

17. The non-transitory computer-readable media of claim 14, wherein the adjusted Vpassr is determined at least in part by adjusting a default Vpassr based on one or both of the following being true: (i) a high amount of the block is open relative to a low amount of the block being open; and/or (ii) a lower number of P/E cycles have been performed by the block relative to a higher number of P/E cycles having been performed by the block.

18. The non-transitory computer-readable media of claim 14, wherein the adjusted Vpassr is at least in part determined based on determining an offset value, and wherein the instructions, when executed by the one or more processors, cause the one or more processors to:
issue a command to adjust a default Vpassr by the offset value to a component of the NAND flash device.

19. The non-transitory computer-readable media of claim 14, wherein performing the read operation includes applying one or more of: (i) the adjusted Vpassr to one or more additional unprogrammed WLs included in the plurality of WLs in addition to the unselected WL; (ii) the adjusted Vpassr to a next unselected WL of the plurality of WLs, the next unselected WL being adjacent the unselected WL and being unprogrammed; or (iii) a default Vpassr to additional unselected unprogrammed ones of the plurality of WLs.

20. The non-transitory computer-readable media of claim 19, wherein the determination of the adjusted Vpassr is based at least in part on the unselected WL being adjacent the selected WL, the plurality of WLs includes a next unselected WL of the plurality of WLs, the next unselected WL having a position adjacent the unselected WL and being unprogrammed, and wherein the instructions, when executed by the one or more processors, cause the one or more processors to:
determine, based at least in part on the position of the next unselected WL, a second adjusted Vpassr,
wherein performing the read operation includes applying the second adjusted Vpassr to the next unselected WL.
